(19) United States
(12) Patent Application Publication
(10) Pub. No.: US 2024/0162730 A1
(43) Pub. Date: May 16, 2024

(54) MOBILE MICROGRID ECOSYSTEM

(71) Applicant: Electric Power Systems, Inc., North Logan, UT (US)

(72) Inventors: Michael Armstrong, North Logan, UT (US); Nathan Millecam, North Logan, UT (US); Steven Hall, North Logan, UT (US); Randy Dunn, Orange, CA (US); Kurt Rose, North Logan, UT (US)

(73) Assignee: Electric Power Systems, Inc., North Logan, UT (US)

(21) Appl. No.: 18/420,462

(22) Filed: Jan. 23, 2024

Related U.S. Application Data
(63) Continuation of application No. PCT/US2022/038549, filed on Jul. 27, 2022.
(60) Provisional application No. 63/226,086, filed on Jul. 27, 2021.
(60) Provisional application No. 63/244,094, filed on Sep. 14, 2021.
(60) Provisional application No. 63/244,108, filed on Sep. 14, 2021.
(60) Provisional application No. 63/313,640, filed on Feb. 24, 2022.
(60) Provisional application No. 63/313,660, filed on Feb. 24, 2022.

(51) Int. Cl. H02J 7/00; B60L 53/16; B60L 53/302; B60L 53/53; B60L 53/65; B60L 53/66; B60L 58/27; H02J 7/34

(52) U.S. Cl. CPC H02J 7/0042; B60L 53/16; B60L 53/302; B60L 53/53; B60L 53/65; B60L 53/665; B60L 58/27; H02J 7/00309; H02J 7/342; B60L 2200/10

(57) ABSTRACT

A mobile microgrid charging system may comprise a first battery array that is configured to be transported from location to location and facilitate fast charging of electric aircrafts. The mobile microgrid charging system is mobile and configured to charge multiple electric aircraft prior to re-charging.

### CROSS-REFERENCE TO RELATED APPLICATIONS

This application is a continuation of PCT Application PCT/US2022/038549 filed Jul. 27, 2022 and titled “MOBILE MICROGRID ECOSYSTEM” (hereinafter the '549 application). The '549 application claims priority to, and the benefit of, Provisional Patent Application No. 63/226,086, filed Jul. 27, 2021 and titled “MOBILE MICROGRID ECOSYSTEM,” Provisional Patent Application No. 63/244,094, filed Sep. 14, 2021 and titled “MOBILE CHARGING SYSTEM WITH BI-DIRECTIONAL DC/DC CONVERTER,” Provisional Patent Application No. 63,244,108, filed Sep. 14, 2021 and titled “FLUID MANAGEMENT SYSTEM FOR MOBILE CHARGING SYSTEM,” Provisional Patent Application No. 63/313,640, filed Feb. 24, 2022 and titled “CROSS-COMPATIBLE BATTERY MODULES FOR MICROGRID SYSTEMS,” Provisional Patent Application No. 63/313,660, filed Feb. 24, 2022 and titled “COMMON BATTERY MODULES INTERFACES FOR MICROGRID SYSTEMS.” Each disclosure of the foregoing applications is incorporated herein by reference in its entireties, including but not limited to those portions that specifically appear hereinafter, but except for any subject matter disclaimers or disavowals, and except to the extent that the incorporated material is inconsistent with the express disclosure herein, in which case the language in this disclosure shall control.

### FIELD OF INVENTION

The present disclosure generally relates to apparatus, systems and methods for cross-compatible battery modules for multi-integration between mobile charging battery systems and aircraft battery systems.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may be inventions.

Charging systems often utilize a significant amount of capital, investment and fixed infrastructure. The fixed infrastructure can be limiting to operations and/or provide a high barrier to electric technology adoption. Additionally, fixed infrastructure may have limitations for charging time and adoption of improvements in the field.

### SUMMARY OF THE INVENTION

A mobile charging system is disclosed herein. In various embodiments, the mobile charging system comprises: a vehicle comprising an electrical system and a motive power system; and a first battery array coupled to the vehicle, the first battery array electrically isolated from the electrical system and the motive power system of the vehicle, the mobile charging system configured to electrically couple the first battery array to a second battery array of an electric vehicle, the mobile charging system configured to charge the second battery array via the first battery array.

In various embodiments, the electric vehicle comprises an electrically powered aircraft.

In various embodiments, the mobile charging system further comprises a thermal management system coupled to the vehicle, wherein the mobile charging system is configured to thermally manage the second battery array via the thermal management system during charging.

A mobile microgrid charging system is disclosed herein. In various embodiments, the mobile microgrid charging system comprises: a first battery array; a charger in electrical communication with the first battery array, the charger including an electrical connector configured to electrically couple the first battery array to a second battery array of a battery system of an electric vehicle; a thermal management system; a supply line extending from the thermal management system to a first fitting; and a return line extending from the thermal management system to a second fitting, the first fitting configured to fluidly couple the supply line to the battery system of the electric vehicle, the second fitting configured to fluidly couple the return line to the battery system.

In various embodiments, the mobile microgrid charging system is configured to transport the first battery array from a first location to a second location, the first location is a fixed electrical grid and the second location is proximal the electric vehicle, and the electric vehicle is an electrically powered aircraft.

In various embodiments, the mobile microgrid charging system further comprises a purge and fill system, a first three-way valve and a second three-way valve, the purge and fill system in fluid communication with the first three-way valve and the second three-way valve, wherein the first three-way valve includes a first inlet in fluid communication with the thermal management system and a second inlet in fluid communication with the purge and fill system.

In various embodiments, the mobile microgrid charging system further comprises electrical cables and a cable refrigeration module, the electrical cables extending from the first battery array to the charger, the mobile microgrid charging system configured to cool the electrical cables during charging of the electric vehicle via the cable refrigeration module.

An electric vehicle charging ecosystem is disclosed herein. In various embodiments, the electric vehicle charging ecosystem comprises: a mobile charging system, comprising: a thermal management system, and a first battery array in electrical communication with a charger, the mobile charging system configured to transport the first battery array from a first location to a second location, and a second battery array configured for powering an electric vehicle, the mobile charging system configured to electrically couple the first battery array to the second battery array by the charger and configured to fluidly couple the thermal management system to a battery system including the second battery array.

In various embodiments, the electric vehicle is an electric aircraft.

In various embodiments, the first battery array is configured to be charged via a fixed electrical grid. The first location can be the fixed electrical grid and the second location can be proximal to the electric vehicle.

In various embodiments, the electric vehicle charging ecosystem further comprises a battery management system and automatic payment system, the battery management system configured to determine a power usage during a charging cycle. In various embodiments, the battery management system is configured to receive an identifier associated with the electric vehicle and transmit the identifier to the automatic payment system. The automatic payment system can be configured to automatically charge a payment method associated with the identifier based on the power usage during the charging cycle.

A method of using a mobile charging system is disclosed herein. In various embodiments, the method comprises: transporting a charging system from a first location to a second location; electrically coupling, through a connector of the mobile charging system, a first battery array of the mobile charging system to a second battery array of an electrically powered aircraft; coupling a plumbing system of the mobile charging system to the electrically powered aircraft; charging the second battery array of the electrically powered aircraft via the first battery array of the mobile charging system, charging the second battery array including heating the first battery array via a fluid being cycled through the plumbing system; and purging the fluid from the electrically powered aircraft.

In various embodiments, the method further comprises powering the electrically powered aircraft with the second battery array.

In various embodiments, the method further comprises heating, via a second thermal management system of the mobile charging system, the second battery array of the electrically powered aircraft. The heating of the second battery array can be performed prior to the charging the second battery array.

In various embodiments, the method further comprises transporting the charging system from the second location to a third location, and charging a third battery array of a second electrically powered aircraft via the first battery array of the mobile charging system.

In various embodiments, the method further comprises cooling electrical cables of mobile charging system during the charging of the second battery array.

### BRIEF DESCRIPTION OF THE DRAWINGS

A more complete understanding of the present disclosure may be derived by referring to the detailed description and claims when considered in connection with the Figures, wherein like reference numbers refer to similar elements throughout the Figures, and where:

FIG. 1 illustrates a method of using a mobile charging ecosystem, in accordance with various embodiments;

FIG. 2A illustrates a schematic view of a mobile charging ecosystem, in accordance with various embodiments;

FIG. 2B illustrates a side view of a mobile charging ecosystem, in accordance with various embodiments;

FIG. 3A illustrates a perspective view of a portion of a battery system, in accordance with various embodiments;

FIG. 3B illustrates a schematic view of a mobile charging ecosystem, in accordance with various embodiments;

FIG. 4 illustrates a schematic view of a system having an automatic payment system for a mobile charging ecosystem, in accordance with various embodiments;

FIG. 5 illustrates a schematic view of a portion of a mobile charging ecosystem, in accordance with various embodiments;

FIG. 6A illustrates a schematic view of a portion of a mobile charging ecosystem, in accordance with various embodiments;

FIG. 6B illustrates a schematic view of a portion of a mobile charging system, in accordance with various embodiments;

FIG. 7A illustrates a schematic view of a portion of a mobile charging ecosystem, in accordance with various embodiments;

FIG. 7B illustrates a schematic view of a portion of a mobile charging system, in accordance with various embodiments;

FIG. 8A illustrates a schematic view of a portion of a mobile charging ecosystem, in accordance with various embodiments;

FIG. 8B illustrates a schematic view of a portion of a mobile charging system, in accordance with various embodiments; and

FIG. 9 illustrates a schematic view of a portion of a mobile charging system, in accordance with various embodiments.

### DETAILED DESCRIPTION

The following description is of various example embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments, without departing from the scope of the appended claims. For example, the steps recited in any of the method or process descriptions may be executed in any order and are not necessarily limited to the order presented. Moreover, many of the manufacturing functions or steps may be outsourced to or performed by one or more third parties. Furthermore, any reference to singular includes plural embodiments, and any reference to more than one component or step may include a singular embodiment or step. Also, any reference to attached, fixed, connected or the like may include permanent, removable, temporary, partial, full and/or any other possible attachment option. As used herein, the terms “coupled,” “coupling,” or any other variation thereof are intended to cover a physical connection, an electrical connection, a magnetic connection, an optical connection, a communicative connection, a functional connection, and/or any other connection.

For the sake of brevity, conventional techniques for mechanical system construction, management, operation, measurement, optimization, and/or control, as well as conventional techniques for mechanical power transfer, modulation, control, and/or use, may not be described in detail herein. Furthermore, the connecting lines shown in various figures contained herein are intended to represent example functional relationships and/or physical couplings between various elements. It should be noted that many alternative or additional functional relationships or physical connections may be present in a modular structure.

A “battery array” as described herein refers to a plurality of batteries electrically coupled together. The term “array” is not meant to be limiting as to size, shape, configuration or the like. Any configuration of batteries coupled in series and/or parallel to form a battery system is within the scope of this disclosure.

In various embodiments, a charging ecosystem (e.g., for use with electric planes, drones, or the like) incorporates an air vehicle having a battery system with a battery management system (BMS), a charger, a microgrid, a thermal management system, Internet of Things (IOT) controls, a battery management Unit (BMU) token management system, and/or a unified framework for communication. The charger, microgrid, thermal management, BMU token management system, and IOT are combined into a mobile charging system that is mobile, in accordance with various embodiments. In various embodiments, the mobility eliminates fixed infrastructure at airports, which would be more costly, harder to service and less functional relative to the mobile charging system disclosed herein. Additionally, the mobility of the mobile charging system may allow the charger to travel to where the aircraft to be charged is located. Thus, fewer charging systems may be utilized at a given airport as the mobile charging system may travel to a parked location of an aircraft as opposed to having to pull the aircraft up to a fixed location, in accordance with various embodiments. The microgrid allows for offsetting the utility peak capacity.

In various embodiments, an aircraft (or multiple aircraft) may be connected to the mobile charging system with power, communication, and/or thermal management cables. The mobile charging system may be able to identify the aircraft through communication to the BMS. The BMS of the aircraft may be registered with payment information so that a point-of-sale (POS) system may be eliminated. The identification of the BMS may initiate the transaction and billing to the registrant of the BMS.

In various embodiments, the mobile charging system may charge the one or more aircraft using stored energy from a microgrid battery system. The BMS of a respective aircraft may transmit data to a control system of the mobile charging system. The control system of the mobile charging system may then transmit this data to various databases, which may store and/or analyze the data. In this regard, the data from the BMS may be used for fleet monitoring, for preventive maintenance and prognostics, degradation modeling, and/or for commissioning of batteries. The charger system may also thermally manage the aircraft batteries during the charge sequence (i.e., heat batteries for fast charging or cool batteries), in accordance with various embodiments as described further herein.

In various embodiments, the charging ecosystem disclosed herein is configured for electric air vehicles (i.e., a plurality of electric aircraft). The charging ecosystem may comprise onboard and offboard assets. In various embodiments, the charging ecosystem involves the combined transfer of energy and data during a charging process. In this regard, the charging ecosystem disclosed herein may facilitate fleet management and allow for greater asset management over time, in accordance with various embodiments. In various embodiments, the charging ecosystem is configured to be mobile to allow the charging system to move between electric aircraft in between charging. In various embodiments, the charging system may include an automatic purge and fill process of an aircraft battery array cooling system. In this regard, the aircraft battery cooling array system may be cleaned on a regular basis increasing efficiency of the cooling system, in accordance with various embodiments. In various embodiments, the charging ecosystem may provide alternative uses for a battery module, such as secondary life of an aircraft battery within the charging ecosystem.

In various embodiments, the charging ecosystem disclosed herein may facilitate flight readiness certification prior to each flight. In this regard, the charging ecosystem disclosed herein may provide enhanced safety of electric aircraft or the like, in accordance with various embodiments. In various embodiments, the charging ecosystem disclosed herein may include an integrated thermal management system configured for warming and cooling of a battery system. In this regard, the charging ecosystem may be configured for fast charging (i.e., heating an aircraft battery during, or before, charging the aircraft battery) and cooling after charging (i.e., returning the aircraft battery to a pre-flight temperature), in accordance with various embodiments.

In various embodiments, the charging ecosystem may be configured for wireless payment (e.g. via a registered token management system or the like). In this regard, an aircraft may be charged after a flight and take-off without initiating a payment or a charging request, in accordance with various embodiments.

In various embodiments, the charging ecosystem disclosed herein provides flexibility of mobile charging, decreasing cost of a charging system relative to a fixed infrastructure, which may facilitate application and adoption of electric aircraft applications. In this regard, by decreasing the cost and increasing the flexibility of charging systems for electric aircraft applications, the capital investment may be decreased, resulting in a greater likelihood of future adoption, in accordance with various embodiments.

In various embodiments, the charging ecosystem disclosed herein facilitates high-rate charging (DCFC) without infrastructure-intensive grid connections. In various embodiments, the charging ecosystem disclosed herein provides simplified logistics for management of an electric aircraft fleet. For example, the mobility of the charging ecosystem permits movement across an airfield, so electric aircraft won't have to be staged at a single area to recharge and/or multiple fixed areas for charging won't have to be built, in accordance with various embodiments.

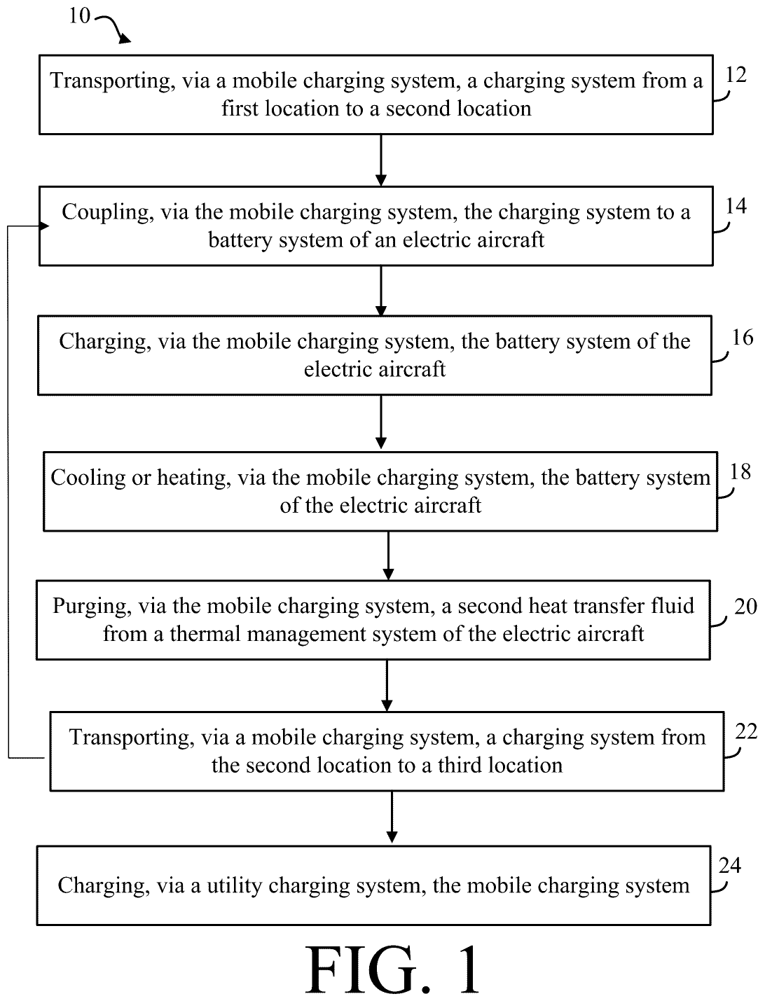

Referring now to FIG. 1, a method of using an electric airplane charging ecosystem, method 10, is illustrated, in accordance with various embodiments. The method 10 comprises transporting, via a mobile charging system, a charging system from a first location to a second location (step 12). The charging system comprises a battery array. In various embodiments, the second location is proximate an electrically powered aircraft. In various embodiments, the first location is a charging station for the mobile charging system. In various embodiments, the first location is proximate another electric aircraft in a plurality of electric aircraft (e.g., a fleet of electric aircraft or the like). In this regard, the mobile charging system is configured to be transported directly from aircraft to aircraft to charge various aircrafts in between being charged itself.

The method 10 further comprises coupling, via the mobile charging system, the charging system to a battery system of the electric aircraft (step 14). The charging system comprises a first battery array and the battery system comprises a second battery array. The first battery array may be located in the mobile charging system, and the second battery array may be located in the aircraft. The first battery array is configured to charge the second battery array. In this regard, coupling the charging system to the battery system includes electrically coupling the first battery array to the second battery array. In various embodiments, coupling the charging system to the battery system further comprises coupling a thermal management system and/or a fill and purge system to the battery system of the electric aircraft. In this regard, the thermal management system may be configured for fast charging (i.e., heating up the second battery array during charging and/or cooling after charging), and the fill and purge system may be configured to purge coolant from the battery system after charging in order to reduce weight of the electric aircraft during operation as described further herein.

The method 10 further comprises charging, via the mobile charging system, the battery system of the electric aircraft (step 16). In various embodiments, charging the battery system may include heating, via a heat pump of the thermal management system of the mobile charging system, the second battery array prior to, or during charging (e.g., between 40° C. and 100° C., or approximately 60° C.). In various embodiments, the charging step further comprises filling (or cycling), via the mobile charging system, the thermal management system of the electric aircraft with a heat transfer fluid used to heat the battery system for fast charging as outlined above and described further herein.

In various embodiments, heating the second battery array may further comprise periodically alternating a flow direction of heat transfer fluid through the battery system for thermal balancing. In this regard, the second battery array may maintain relatively balanced temperature across all battery modules in the second battery array relative to a single direction of flow where a temperature gradient would likely occur across the battery modules.

In various embodiments heating the battery system prior to or during charging may facilitate fast charging. For example, in various embodiments, the battery array of the battery system is heated with a fluid having a temperature at approximately 60° C. to increase lithium graphite intercalation of cells in a battery module by approximately 13 times that of typical fast charging systems and significantly reduce lithium plating. In various embodiments, the heating of the battery array with a heat transfer fluid at a temperature as disclosed herein may increase a rate at which the lithium diffuses into the graphite. The rate at which the lithium diffuses into the graphite is increased approximately 6 times in typical fast charging systems. In various embodiments, the heating of the battery array with a fluid at a temperature as disclosed herein may increase an electrolyte conductivity by approximately 9 times relative to typical fast charging systems.

In various embodiments, charging the battery system may comprise discharging the first battery array of the mobile charging system with a first discharge profile. In various embodiments, the first discharge profile may have a C-rate between C/10 and C/2, or between C/8 and C/5. In various embodiments, the mobile charging system may be configured to discharge near fully over an entire day. For example, the mobile charging system may charge five aircraft in a day after leaving a fixed charging station and return to the fixed charging station at the end of the day, in accordance with various embodiments. In this regard, the battery system of the mobile charging system may have less wear relative to the battery system of the electric aircraft which may discharge near fully multiple times a day (i.e., through multiple flight cycles), in accordance with various embodiments. In various embodiments, low rate charging and discharging may provide low degradation. In various embodiments, by discharging the mobile charging system only a single time over a day, cumulative cycles for the mobile charging system may also be relatively low.

In various embodiments, the method 10 further comprises cooling or heating, via the mobile charging system, the battery system of the electric aircraft (step 18). For example, the mobile charging system may heat the battery system of the electric aircraft during charging and cool the battery system of the electric aircraft after charging, in accordance with various embodiments. The battery system of the electric aircraft may still be in a relatively hot temperature environment prior to the cooling step from heating during charging. Thus, by cooling the battery system of the electric aircraft after fast charging, the battery system may be returned to a more efficient temperature environment for operation of the electric aircraft, in accordance with various embodiments.

In various embodiments, cooling the battery system of the electric aircraft may further comprise periodically alternating a flow direction of heat transfer fluid through the battery system for thermal balancing. In this regard, the battery system of the electric aircraft may maintain relatively balanced temperature across all battery modules in the battery system of the electric aircraft relative to a single direction of flow where a temperature gradient would likely occur across the battery modules.

In various embodiments, the method 10 further comprises purging, via the mobile charging system, the heat transfer fluid used in the charging step (e.g., step 18) from the battery system of the aircraft (step 20). In this regard, by purging the heat transfer fluid after a charging cycle is complete, any weight from the fluid of the thermal management system of the electric aircraft may be removed prior to flight. Thus, by utilizing a purge and fill system as disclosed herein, weight of an electric aircraft may be significantly reduced, in accordance with various embodiments.

In various embodiments, after utilizing the thermal management system of the mobile charging system in accordance with method 10, the electric aircraft may be powered via the battery system that was charged in method 10. For example, the battery system may be configured to power, via the second battery array of the battery system, the electric aircraft. In various embodiments, the second battery array may comprise a second discharge profile that is greater than the first discharge profile of the first battery array of the charging system. For example, the second battery array may comprise a second discharge profile between C/2 and 3C or between 1C and 2C in accordance with various embodiments. In various embodiments, the first battery array of the charging system and the second battery array of the battery system of the electric aircraft may comprise differing charging profiles as well. For example, the first battery array of the charging system may be configured to charge over a long duration (e.g., overnight). In this regard, the first battery array of the charging system may have a charging profile between C/10 and C/5 or between C/9 and C/6, in accordance with various embodiments. In contrast, the charging rate of the second battery array of the battery system for the electric aircraft may be significantly faster than the first battery array of the charging system. For example, the charging rate of the second battery array may be between 1C and 10C or between 2C and 8C, or approximately 5C, in accordance with various embodiments. Thus, the system may be configured to charge the first battery at a significantly lower C rate than it is discharged.

In various embodiments, steps 16-20 can be performed by a single mobile charging system (e.g., a mobile charging system having multiple chargers) in a single location (e.g., the second location) to charge multiple electric aircraft at the same time. In various embodiments, a mobile charging system can repeat steps 12 through 20 multiple times a day prior to charging a battery system of the mobile charging system as described previously herein.

In various embodiments, the method 10 further comprises transporting, via the mobile charging system, the charging system to a third location (step 22). In various embodiments, the first location may be in accordance with the third location (i.e., when the first location is a utility charging station, or the like configured to charge the charging system of the mobile charging system). In various embodiments, the third location is a location proximate another electric aircraft, or multiple electric aircraft. In response to the third location being proximate an electric aircraft (i.e., in response to the mobile charging system not having to be re-charged), steps 14-20 can be repeated at the third location as described previously herein.

In various embodiments, in response to the third location being a charging station (i.e., in response to the mobile charging system having to be re-charged, the method 10 further comprises charging, via the utility charging system, the charging system of the mobile charging system (step 24). In this regard, the first battery array of the charging system may have a charging profile between C/10 and C/5 or between C/9 and C/6, as described previously herein. The first battery array of the charging system may be configured to charge over a long duration (e.g., between 6 and 12 hours, or approximately 8 hours). Thus, the charging system of the mobile charging system may charge over night and discharge over an entire day, through multiple charging cycles of various electric aircrafts, in accordance with various embodiments.

In various embodiments, the method 10 may be repeated for additional electric aircrafts throughout a day. In various embodiments, the method 10 may be utilized to charge multiple electric aircrafts simultaneously. In this regard, the mobile charging system may include a plurality of connectors, in accordance with various embodiments.

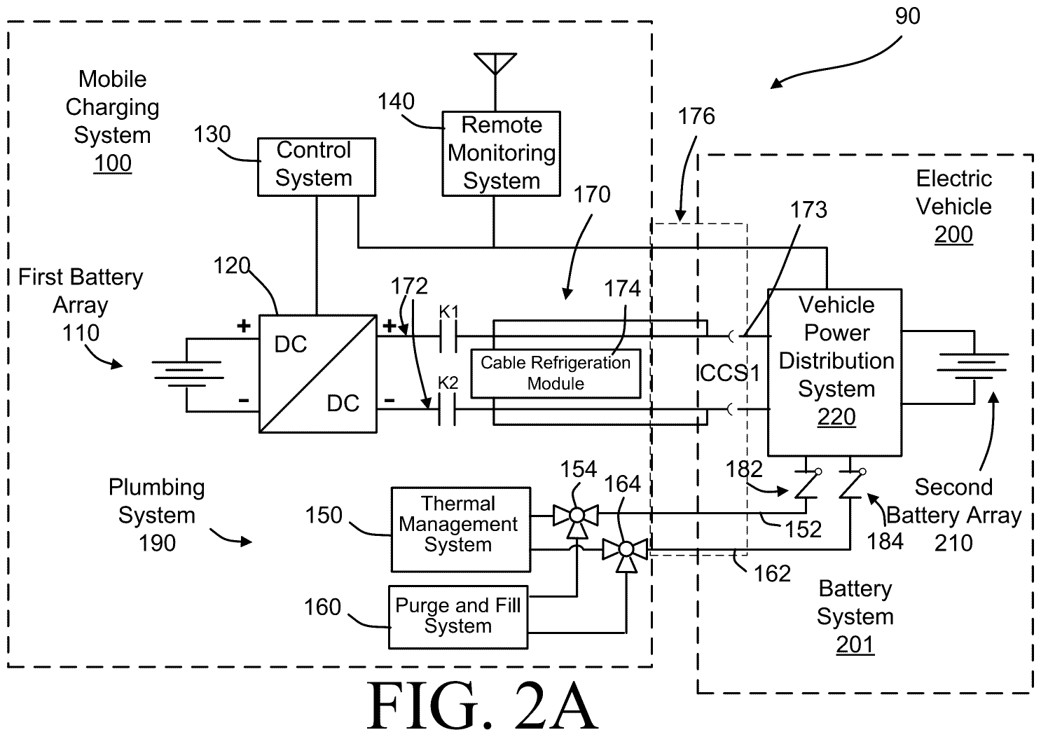

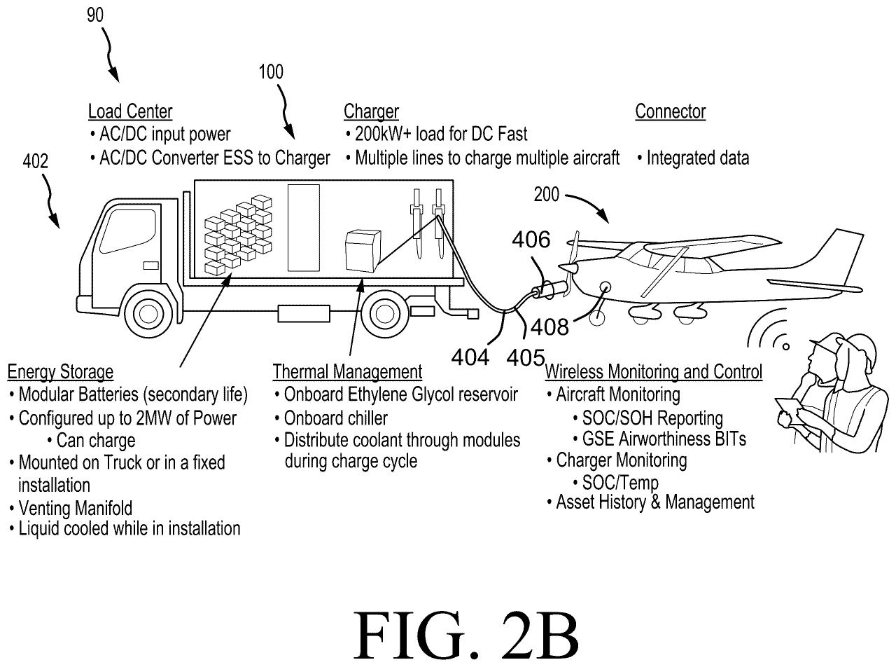

Referring now to FIGS. 2A and 2B, a schematic view (FIG. 2A) and a side view (FIG. 2B) of an electric vehicle charging ecosystem 90 (e.g., a mobile charging ecosystem) is illustrated, in accordance with various embodiments. The electric vehicle charging ecosystem 90 may be configured for charging (e.g., in accordance with method 10 of FIG. 1) an electrically powered aircraft (e.g., a battery powered aircraft or the like). The electric vehicle charging ecosystem 90 comprises a mobile charging system 100 (e.g. a mobile microgrid) and an electric vehicle 200 (e.g., an electric aircraft) with a battery system 201 (e.g., a vehicle battery system). The mobile charging system 100 comprises a first battery array 110. Similarly, the electric vehicle 200 comprises a second battery array 210. As described previously herein, the second battery array 210 is configured to power the electric vehicle (e.g., an electric powered aircraft or the like), for flight, in accordance with various embodiments.

In various embodiments, the mobile charging system 100 comprises a first battery array 110, a bi-directional direct current (DC)/DC converter 120, a control system 130, a remote monitoring system 140, a thermal management system 150, and/or a purge and fill system 160. In various embodiments, the first battery array 110 may be configured to charge the second battery array 210 of the electric vehicle as described further herein. In various embodiments, the first battery array 110 may be configured to be charged via a fixed electrical grid (e.g., configured to receive AC/DC input power) or the like prior to charging a plurality of electrical vehicles as described with respect to method 10 from FIG. 1. In various embodiments, the bi-directional DC/DC converter 120 is in operable communication with the control system 130. In this regard, the control system 130 may be configured to control charging of the second battery array 210 by the first battery array 110 through the DC/DC converter 120 and/or control charging the first battery array 110 via a fixed electrical grid through the bi-directional DC/DC converter 120 as described further herein. In various embodiments, the first battery array 110 may be mounted within a vehicle (e.g., a vehicle 402 or the like as shown in FIG. 2B) or be fixedly installed on a vehicle. In various embodiments, the first battery array 110 may be a component of an energy storage system of the mobile charging system 100. The energy storage system may include a venting manifold, in accordance with various embodiments. Although disposed within, or mounted to the vehicle 402 of FIG. 2B, the first battery array 110 is not configured to power the vehicle 402. In this regard, the first battery array 110 is configured for charging an electric vehicle (e.g., electric vehicle 200) and being charged by a power grid or the like. In this regard, the first battery array 110 can be electrically isolated from a power system and/or an electrical system of the vehicle 402, in accordance with various embodiments.

In various embodiments, the electric vehicle charging ecosystem 90 comprises a combined charging system (CCS) 170 configured for high-power DC fast charging. For example, the CCS 170 can comprise a combo plug 173. Although illustrated as comprising combo plug 173 in accordance with a United States style combined charging system (CCS1), the charging system is not limited in this regard. For example, the combo plug 173 of the combined charging system 170 may comprise a European style combined charging system (CCS2), Chademo, GBT, or any other emerging aerospace standard charging system, in accordance with various embodiments.

In various embodiments, the mobile charging system includes electrical cables 172 and a cable refrigeration module 174. The electrical cables 172 extend from the bi-directional DC/DC converter 120 to a combo plug 173 of the combined charging system 170. The combo plug 173 of the combined charging system 170 is configured to be electrically coupled to a socket of the combined charging system 170. In various embodiments, the combo plug 173 is a component of the mobile charging system 100 and the socket is a component of the electric vehicle 200 or vice versa. The present disclosure is not limited in this regard. In various embodiments, the cable refrigeration module 174 may make handling of the electrical cables 172 easier for a ground personnel during charging.

In various embodiments, the cable refrigeration module 174 is configured to cool the electrical cables 172 during fast charging. For example, due to the high-power charging disclosed herein, the electrical cables may become overheated. In this regard, the cable refrigeration module 174 may be configured to maintain a safe and efficient temperature of the electrical cables 172 for efficient fast charging, in accordance with various embodiments. In various embodiments, also permits use of smaller diameter cables, making the electrical cables lighter and easier to handle by the ground crew.

In various embodiments, the bi-directional DC/DC converter 120 is configured to act as an impedance matching device. In this regard, the bi-direction DC/DC converter 120 is configured to allow power to be shuttled to and from the second battery array 210 of the battery system 201 of the electric vehicle 200, thereby enabling advanced battery state of health estimation at every charge cycle, in accordance with various embodiments. In this regard, control system 130 may be configured to estimate battery state of health and state of charge for the second battery array 210, each charge cycle. Control system 130 may further provide a certification or approval of flight worthiness for the battery at each charge cycle. In various embodiments, in response to a battery module within the second battery array reaching a useful life on the electric vehicle, the battery module may have a secondary life on the mobile charging system 100.

After purging the working fluid via the purge and fill system 160, the plumbing system 190 of the mobile charging system 100 may supply a heat transfer fluid, via the thermal management system 150, to the battery system to heat the second battery array 210 to a predetermined temperature for fast charging. The heat transfer fluid may be configured to heat the second battery array 210 to a temperature between 40° C. and 100° C., or more preferably approximately 60° C. In various embodiments, by heating the second battery array 210 with the working fluid of the thermal management system 150 to a temperature at approximately 60° C. may increase lithium graphite intercalation of cells in a battery module by approximately 13 times that of typical fast charging systems and significantly reduce lithium plating.

In various embodiments, after charging of the second battery array is completed, the purge and fill system 160 may purge any remaining heat transfer fluid remaining from operation of the thermal management system 150 in the plumbing system 190. In various embodiments, after charging the battery system of the electric vehicle, the purge and fill system 160 may be configured to re-fill a thermal management system of the battery system 201 of the electric vehicle 200. In this regard, the purge and fill system 160 may be configured to purge a working fluid within the battery system 201 and/or re-fill the battery system with a new heat transfer fluid during each charge cycle for a respective electric vehicle (e.g., method 10 from FIG. 1). However, the present disclosure is not limited in this regard. For example, the purge and fill system 160 could be used only as a purge system for use before and/or after charging, or only as a fill system for use after charging and remain within the scope of this disclosure.

In various embodiments, the thermal management system 150 and the purge and fill system 160 each connect to the vehicle via fittings 182, 184 (e.g., dripless quick-disconnect fittings). In various embodiments, the thermal management system 150 and the purge and fill system 160 are isolated by using electrically controlled, three-way valves 154, 164 (i.e., only the thermal management system 150 or the purge and fill system 160 may be used at a single instance). In this regard, the thermal management system 150 and the purge and fill system 160 may be used sequentially as outlined above, in accordance with various embodiments.

In various embodiments, a supply line 152 extends from an output of the first three-way valve 154 to the first fitting 182. Similarly, a return line 162 extends from an input of the second three-way valve 164 to the second fitting 184. In this regard, the first three-way valve 154 may have two inputs (e.g., to either the thermal management system 150 or to the purge and fill system 160) and a single output (e.g., to the supply line 152), whereas the second three-way valve 164 may have a single input (e.g., from the return line 162) and two outputs (e.g., to either the thermal management system 150 or the purge and fill system 160. Thus, fluid associated with the thermal management system 150 or with the purge and fill system 160 may be configured to cycle through the plumbing system 190 via the supply line 152 and return line 162, in accordance with various embodiments.

In various embodiments, the control system 130 comprises a supervisory control and data acquisition system (SCADA). In this regard, the SCADA system may be configured to monitor and control processes of the mobile charging system 100 from a remote location.

In various embodiments, the remote monitoring system 140 is in operable communication with a vehicle power distribution system 220 in response to the remote monitoring system 140 being electrically coupled to the remote monitoring system 140 or in response to the electric vehicle becoming in range of a wireless network of the remote monitoring system. In various embodiments, the remote monitoring system 140 comprises remote telemetry (i.e., a remote telemetry unit (RTU) with a microprocessor-based remote device configured to monitor and report events of the vehicle power distribution system 220). The remote monitoring system 140 may be configured to communicate with the vehicle power distribution system 220 of the electric vehicle through a wireless or wired connection. The present disclosure is not limited in this regard. In various embodiments, the vehicle power distribution system communicates with the remote monitoring system view a wireless network. In this regard, in response to the vehicle power distribution system becoming in range of the wireless network, the vehicle power distribution system 220 may be configured to transfer information related to operation history of the second battery array 210 to the remote monitoring system 140. In this regard, battery modules within the second battery array 210 may be continuously monitored for airworthiness, in accordance with various embodiments.

Although the fluid lines for the thermal management system 150 and the purge and fill system 160 are illustrated separately from the electrical cables 172 and the communication lines from the control system 130, the present disclosure is not limited in this regard. For example, the plumbing lines from thermal management system 150 and/or the purge and fill system 160, as well as communications connectors of the control system 130 may be integral with a connector or plug of the combined charging system 170. In this regard, in response to coupling a connector of the combined charging system 170 to the electric vehicle 200 (i.e., in accordance with step 14 from FIG. 1), the fittings 182, 184 may be coupled to the electric vehicle 200, and/or the control system 130 may become in operable communication with the vehicle power distribution system 220, in accordance with various embodiments. In various embodiments, the control system 130 may be in wireless communication (e.g., via Wi-Fi or a network) with the vehicle power distribution system 220 of electric vehicle 200.

In various embodiments, there are three specific couplings between of the mobile charging system 100 and the battery system 201 of the electric vehicle 200: (1) power (i.e., electrical coupling of the combined charging system 170), (2) data (i.e., electronic coupling of remote monitoring system 140 and/or control system 130 to the vehicle power distribution system 220), and (3) thermal (i.e., operable coupling of thermal management system 150 and purge and fill system 160). Each of these couplings can be made independently or in any combinations of the three, in accordance with various embodiments.

In various embodiments, the vehicle power distribution system 220 is configured to distribute the power from the second battery array 210 to various electrically powered components of the electric vehicle (e.g., and electrical compressor, an electric motor, an electric fan, etc.). In this regard, an electric vehicle may be powered through the vehicle power distribution system 220 utilizing the second battery array 210 of the electric vehicle, in accordance with various embodiments. In various embodiments, the vehicle power distribution system 220 is also configured to facilitate charging of the second battery array 210 from the mobile charging system 100.

Referring now to FIG. 2B, a schematic view of the electric vehicle charging ecosystem 90 is illustrated, in accordance with various embodiments. The electric vehicle charging ecosystem 90 comprises the mobile charging system 100 and the electric vehicle 200. In various embodiments, the mobile charging system 100 comprises a vehicle 402. The vehicle can comprise any type of vehicle configured to move from one location to another (e.g., a truck, a car, a motorcycle, a plane, a boat, etc.). The present disclosure is not limited in this regard. In various embodiments, the vehicle 402 comprises a motive power system (e.g., an internal combustion engine for a car, a battery system for a car, a hydrogen-powered system, a gas turbine engine for a plane, etc.) and an electrical system (e.g., configured to power electronics within the vehicle). In various embodiments, the first battery array 110 described previously herein is electrically isolated from the motive power system and the electrical system.

In various embodiments, the mobile charging system 100 further comprises a charger 404. In various embodiments, the charger 404 comprises a harness 405 and a connector 406. In various embodiments, the harness 405 is configured to house various electrical wiring (e.g., wiring to electrically couple the control system 130 to the vehicle power distribution system 220, the combined charging system 170, etc.) and/or various fluid conduits (e.g., a portion of supply line 152 and/or return line 162). In various embodiments, the connector 406 is configured to couple to a connector of the electric vehicle 200. In this regard, in response to coupling the connector 406 of the mobile charging system 100 to the connector 408 of the electric vehicle 200, the mobile charging system 100 and the electric vehicle 200 are electrically and thermally coupled in the manner shown in FIG. 2A. In this regard, in response to coupling the connector 406 of the mobile charging system 100 to the connector 408 of the electric vehicle 200, the mobile charging system 100 can be configured to facilitate charging of the second battery array 210 of the electric vehicle via the first battery array 110 of the mobile charging system 100 as described previously herein.

In various embodiments, the mobile charging system 100 can be configured to charge multiple electric vehicles 200 simultaneously. In this regard, in various embodiments, the mobile charging system 100 can comprise a plurality of the charger 404. Each charger in the plurality of the charger 404 can be configured to be coupled to an aircraft. In this regard, multiple electric vehicles 200 (e.g., electrically powered aircrafts) can be charged simultaneously, in accordance with various embodiments.

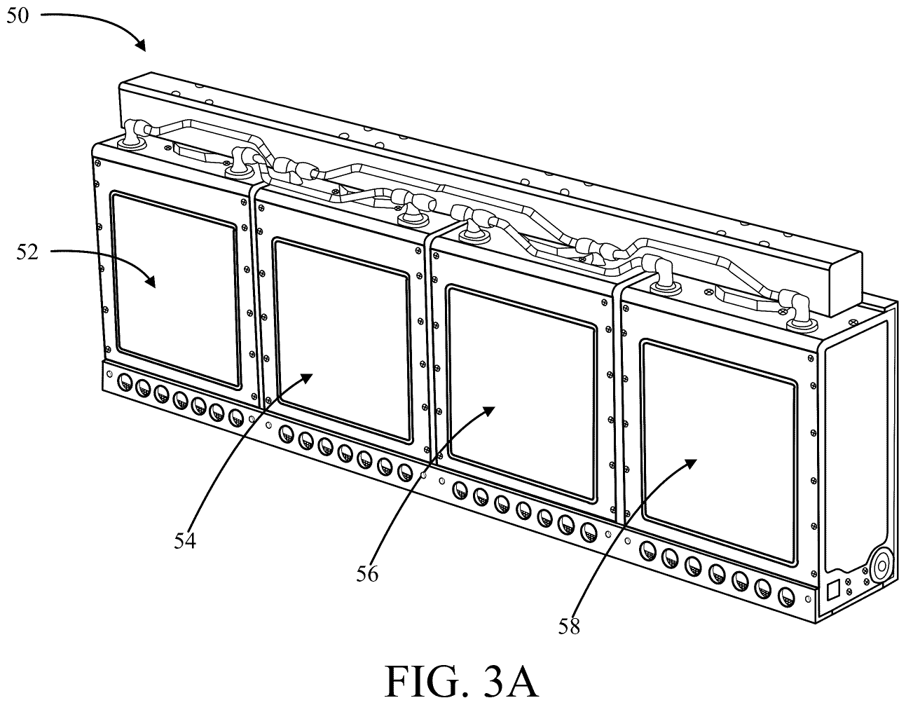

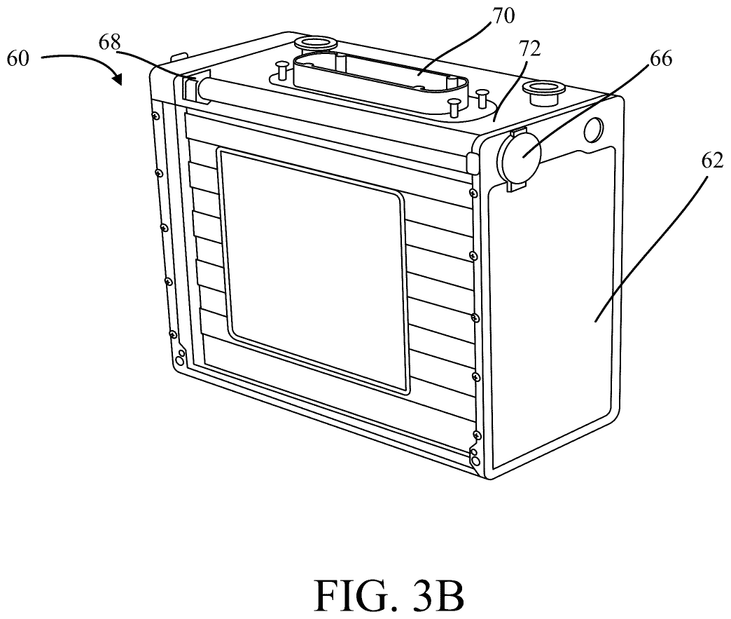

Referring now to FIG. 3A, a perspective view of a portion of an interconnected battery system 50 (e.g., the first battery array 110 or the second battery array 210 from FIG. 2A) is illustrated, in accordance with various embodiments. In various embodiments, the interconnected battery system 50 includes a plurality of interconnected battery modules (“ICBM” or “ICBMs”) (e.g., interconnected battery modules 52, 54, 56, 58). In various embodiments, each interconnected battery module (e.g., ICBMs 52, 54, 56, 58) includes a plurality of cells disposed therein. The plurality of cells may be cylindrical cells, prismatic cells, pouch cells, or any other cell. In various embodiments, the plurality of cells are a plurality of pouch cells.

In an example embodiment, an ICBM (e.g., ICBMs 52, 54, 56, 58) as disclosed herein may comprise a nominal voltage of approximately 7 volts, a capacity of approximately 50 ampere-hours, an energy output of approximately 0.36 kWh, or the like. Although an example ICBM may have these specifications, an interconnected battery module of any specification is within the scope of this disclosure. For example, an ICBM (e.g., ICBMs 52, 54, 56, 58) as disclosed herein may comprise a nominal voltage of approximately 39 volts, a capacity of approximately 60 ampere-hours, an energy output of approximately 2.3 kWh, or the like. In an example embodiment, a 1,000 volt interconnected battery module system may be created by interconnecting one-hundred and thirty-six ICBMs in series as disclosed herein. In various embodiments, by having each ICBM isolated and discrete from the remaining ICBMs, a thermal runaway event may be limited to a single ICBM where the thermal runaway event occurs. In this regard, in accordance with various embodiments, an ICBM, as disclosed herein, may be configured to contain a thermal runaway event of a cell disposed in the ICBM without affecting any cell in any of the remaining ICBMs.

Referring now to FIG. 3B, a perspective view of an ICBM 60 is illustrated with a translucent housing, in accordance with various embodiments. In various embodiments the ICBM 60 includes a housing 62 and a plurality of cells disposed in the housing 62. In various embodiments, the plurality of cells are a plurality of pouch cells. In various embodiments, the ICBM 60 includes a positive terminal 66 disposed on a first side of the housing 62 and a negative terminal 68 disposed on a second side of the housing 62.

In various embodiments, the positive terminal 66 is configured to electrically and physically couple to a negative terminal (e.g., negative terminal 68) of an adjacent ICBM in an interconnected battery system (e.g., interconnected battery system 50 from FIG. 3A) Similarly, the negative terminal 68 is configured to electrically and physically couple to a positive terminal (e.g., positive terminal 66) of an adjacent ICBM in an interconnected battery system (e.g., interconnected battery system 50 from FIG. 3A). In this regard, the ICBMs of interconnected battery system 50 may be configured for electrical and physical coupling in series electrically. However, in other example embodiments, the ICBMs may be configured with an additional component to create a parallel electrical connection, in accordance with various embodiments. The present disclosure is not limited in this regard. For example, the interconnected battery system 50 of FIG. 3A may be configured to couple adjacent ICBMs in parallel as a default configuration instead of in series as a default configuration and still be within the scope of this disclosure.

In various embodiments, the housing 62 includes a vent port 70. In various embodiments, the vent port 70 is a fluid outlet in the plurality of fluid outlets in an interconnected battery system 50 from FIG. 3A. In various embodiments, the vent port 70 is disposed on a top surface of the housing 62. The vent port 70 is in fluid communication with an internal cavity 72 of the housing 62. The plurality of cells are also disposed in the internal cavity 72. In this regard, any ejecta, gases, or foreign object debris (“FOD”) from a thermal runaway event may be configured to be expelled out the vent port 70 and into a common vent and out of the interconnected battery system (e.g., interconnected battery system 50 from FIG. 3A).

In various embodiments, the first battery array 110 from FIG. 2A comprises a plurality of ICBMs (e.g., ICBMs 52, 54, 56, 58 from FIG. 3A). In various embodiments, a total energy output for the first battery array 110 may be between 50 kWh and 1.5 MWh, or between 100 kWh and 1 MWh, or approximately 250 kWh.

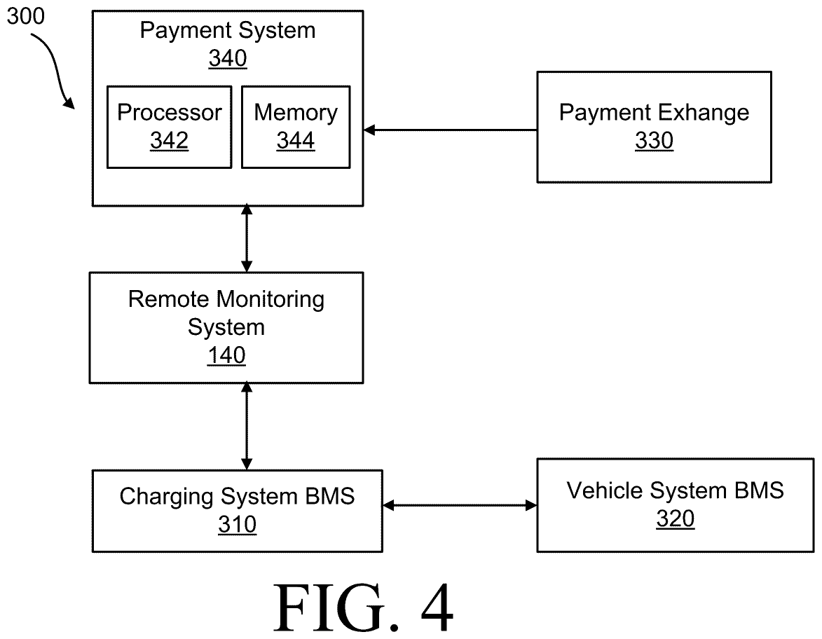

Referring now to FIG. 4, a schematic view of a payment management system 300 for an electric vehicle charging ecosystem 90 is illustrated, in accordance with various embodiments. In various embodiments, the mobile charging system 100 of FIG. 2A further comprises a charging system battery management system (BMS) 310. The charging system BMS 310 is configured to manage the first battery array 110 of the mobile charging system 100, such as by protecting the first battery array 110 from operating outside of predetermined operation parameters, monitor a state of charge, calculating secondary data, reporting the data, controlling an environment of the first battery array 110 (i.e., through a thermal management system or the like), and/or balancing the first battery array 110, in accordance with various embodiments. In various embodiments, the charging system BMS 310 is a component of the control system 130.

In various embodiments, the electric vehicle 200 of FIG. 2A comprises an electric vehicle BMS 320. The electric vehicle BMS is configured to manage the second battery array 210 of the electric vehicle, such as by protecting the second battery array 210 from operating outside of predetermined operation parameters, monitor a state of charge, calculating secondary data, reporting the data, controlling an environment of the second battery array 210 (i.e., through a thermal management system or the like), and/or balancing the second battery array 210, in accordance with various embodiments. In various embodiments, the electric vehicle BMS 320 is a component of the vehicle power distribution system 220.

In various embodiments, the charging system BMS is in operable communication with the remote monitoring system 140. In various embodiments, the remote monitoring system 140 may be in communication with a payment system 340 configured for automatic payment in response to an electric charging method (e.g., method 10 from FIG. 1. For example, the charging system BMS 310 may transmit usage data to remote monitoring system 140 corresponding to a respective charge cycle (e.g., from step 18 of method 10 from FIG. 1) and/or a respective identifier for an electric vehicle being charged (e.g., a tail number for an electric aircraft). The usage data and the identifier may then be transmitted to an automatic payment system 340.

In various embodiments, the payment system 340 comprises a processor 342 and a memory 344. In various embodiments, and as shown in FIG. 2B, payment system 340 may store a software program configured to perform the methods described herein in the memory 344 and run the software program using the processor 342. The payment system 340 may include any number of individual processors 342 and memories 344. Various data may be communicated between the payment system 340 and a user (e.g., an owner of the electric vehicle 200 from FIG. 2A) via a payment user interview (UI). Such information may also be communicated between the secure payment system 340 and the financial institutions (e.g., payment exchange 330) and/or any other computing device connected to the payment system 340 (e.g., through any network such as a local area network (LAN), or wide area network (WAN) such as the Internet).

In various embodiments, in payment system 340, the processor 342 retrieves and executes instructions stored in the memory 344 to control the operation of the payment system 340. Any number and type of processor(s) (e.g., an integrated circuit microprocessor, microcontroller, and/or digital signal processor (DSP)), can be used in conjunction with the various embodiments. The processor 342 may include, and/or operate in conjunction with, any other suitable components and features, such as comparators, analog-to-digital converters (ADCs), and/or digital-to-analog converters (DACs). Functionality of various embodiments may also be implemented through various hardware components storing machine-readable instructions, such as application-specific integrated circuits (ASICs), field-programmable gate arrays (FPGAs) and/or complex programmable logic devices (CPLDs).

The memory 344 may include a non-transitory computer-readable medium (such as on a CD-ROM, DVD-ROM, hard drive or FLASH memory) storing computer-readable instructions thereon that can be executed by the processor 342 to perform the methods of the present disclosure. The memory 344 may include any combination of different memory storage devices, such as hard drives, random access memory (RAM), read only memory (ROM), FLASH memory, or any other type of volatile and/or nonvolatile memory.

The payment system 340 may receive the usage data about a respective charge cycle and an identifier of an electric vehicle being charged from the charging system BMS 310 (either directly from the charging system BMS 310 or through the remote monitoring system 140), in accordance with various embodiments. In various embodiments, various owners of various electric vehicles to be charged may register their vehicle identifier with the payment system 340 along with a payment method (e.g., a credit card, a bank account, or the like). In various embodiments, in response to receiving the usage data about the respective charge and the identifier, the payment system 340 may compare the identifier to a plurality of vehicle identifiers stored in the memory 344. In response to finding a matching identifier in the memory 344, the payment system 340 may determine the payment method associated with the matching identifier and pull the payment from the payment exchange 330 associated with the respective payment method, in accordance with various embodiments. In various embodiments, the payment system disclosed herein may allow a user to automatically pay for charging an electric vehicle (e.g., electric vehicle 200 from FIG. 2A) without a user-initiated payment or a charging request. Thus, the payment system 340 may facilitate a faster transition between flights for a respective owner of an electric vehicle 200, in accordance with various embodiments.

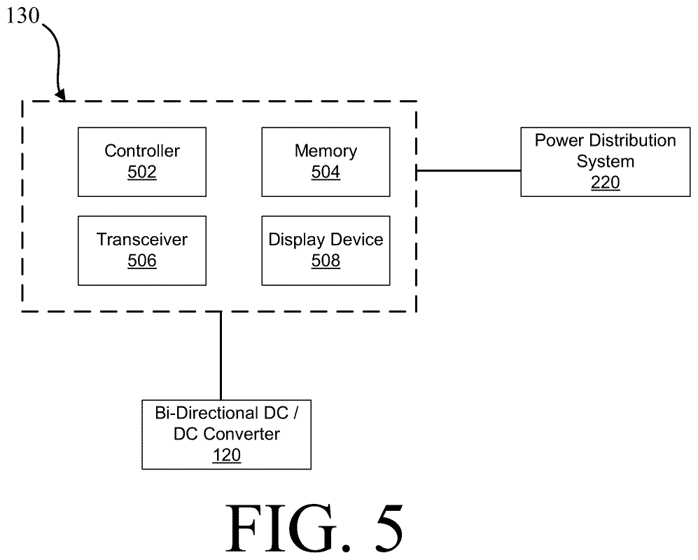

Referring now to FIG. 5, a schematic view of the control system 130 from FIGS. 2A and 2B is illustrated, in accordance with various embodiments. In various embodiments, the control system 130 comprises a controller 502 and a memory 504. In various embodiments, controller 502 may be integrated into computer system of the mobile charging system 100 from FIGS. 2A and 2B. In various embodiments, controller 502 may be configured as a central network element or hub to access various systems and components of control system 130. Controller 502 may comprise a network, computer-based system, and/or software components configured to provide an access point to various systems and components of control system 130. In various embodiments, controller 502 may comprise a processor. In various embodiments, controller 502 may be implemented in a single processor. In various embodiments, controller 502 may be implemented as and may include one or more processors and/or one or more tangible, non-transitory memories and be capable of implementing logic. Each processor can be a general purpose processor, a digital signal processor (“DSP”), an application specific integrated circuit (“ASIC”), a field programmable gate array (“FPGA”) or other programmable logic device, discrete gate or transistor logic, discrete hardware components, or any combination thereof. Controller 502 may comprise a processor configured to implement various logical operations in response to execution of instructions, for example, instructions stored on a non-transitory, tangible, computer-readable medium (e.g., memory 504) configured to communicate with controller 502.

System program instructions and/or controller instructions may be loaded onto a non-transitory, tangible computer-readable medium having instructions stored thereon that, in response to execution by a controller, cause the controller to perform various operations. The term “non-transitory” is to be understood to remove only propagating transitory signals per se from the claim scope and does not relinquish rights to all standard computer-readable media that are not only propagating transitory signals per se. Stated another way, the meaning of the term “non-transitory computer-readable medium” and “non-transitory computer-readable storage medium” should be construed to exclude only those types of transitory computer-readable media which were found in In Re Nuijten to fall outside the scope of patentable subject matter under 35 U.S.C. § 101.

In various embodiments, the control system 130 further comprises a transceiver 506 and a display device 508. The transceiver may be configured to communicate with external systems from the control system 130 (e.g., vehicle power distribution system 220 and/or bi-directional DC/DC converter 120). In various embodiments, the bi-directional DC/DC converter 120 may be electrically coupled to the control system 130. The present disclosure is not limited in this regard. In various embodiments, the display device 508 may be in electronic (e.g., wireless or wired) communication with the controller 502.

Referring now to FIGS. 1, 2A, and 5, a charging step 16 of method 10 can be performed by the control system 130 from FIGS. 2A and 5, in accordance with various embodiments. For example, the controller 502, through the bi-directional DC/DC converter 120, can command a first battery array (e.g., the first battery array 110 from FIG. 2A), to charge a second battery array (e.g., the second battery array 210 of the electric vehicle 200 from FIG. 2A). In this regard, the bi-directional DC/DC converter 120 is configured to match the input impedance of the first battery array 110 to an output impedance for charging the second battery array 210 to maximize power transfer and/or minimize signal reflection from the charging.

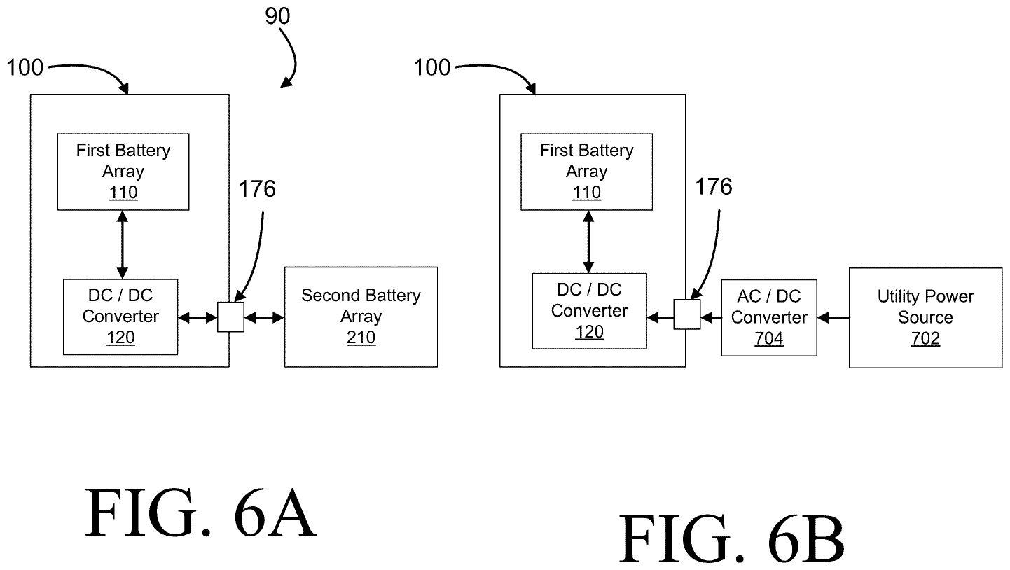

Referring now to FIGS. 6A and 6B, a schematic view of the electric vehicle charging ecosystem 90 (FIG. 6A) and a schematic system of charging of the mobile charging system 100 (FIG. 6B) are illustrated, in accordance with various embodiments. In various embodiments, during charging (e.g., charging step 16 of method 10 from FIG. 1) of the second battery array 210 as shown in FIG. 6A, the bi-directional DC/DC converter 120 is configured to shuttle current from the first battery array 110 to the second battery array 210 in during charging (i.e., during charging step 16 of method 10 from FIG. 1).

In various embodiments, the mobile charging system 100 comprises a charging interface 176. The charging interface 176 may be a component of the combined charging system 170 from FIG. 2A. In this regard, the charging interface 176 may be a socket configured to receive a combo plug 173 from FIG. 2A or the like. However, separate plugs are within the scope of this disclosure. The present disclosure is not limited in this regard.

In various embodiments, the mobile charging system 100 is configured to be charged via an alternating current (A/C) source (e.g., a utility power source 702). In this regard, the alternating current provided by the utility power source 702 may be converted via an AC/DC converter 704. The AC/DC converter 704 may be electrically coupled to the charging interface 176 of the mobile charging system 100, and the AC/DC converter 704 may be electrically coupled to the utility power source 702 to charge the first battery array 110. The common charging interface 176 may be utilized for charging the second battery array 210 via the first battery array 110 (e.g., via the charging step 16 of method 10 from FIG. 1), and for charging the first battery array 110 from the utility power source 702 (FIG. 6B). Thus, the mobile charging system 100 is adaptable for various charging and being charged, in accordance with various embodiments.

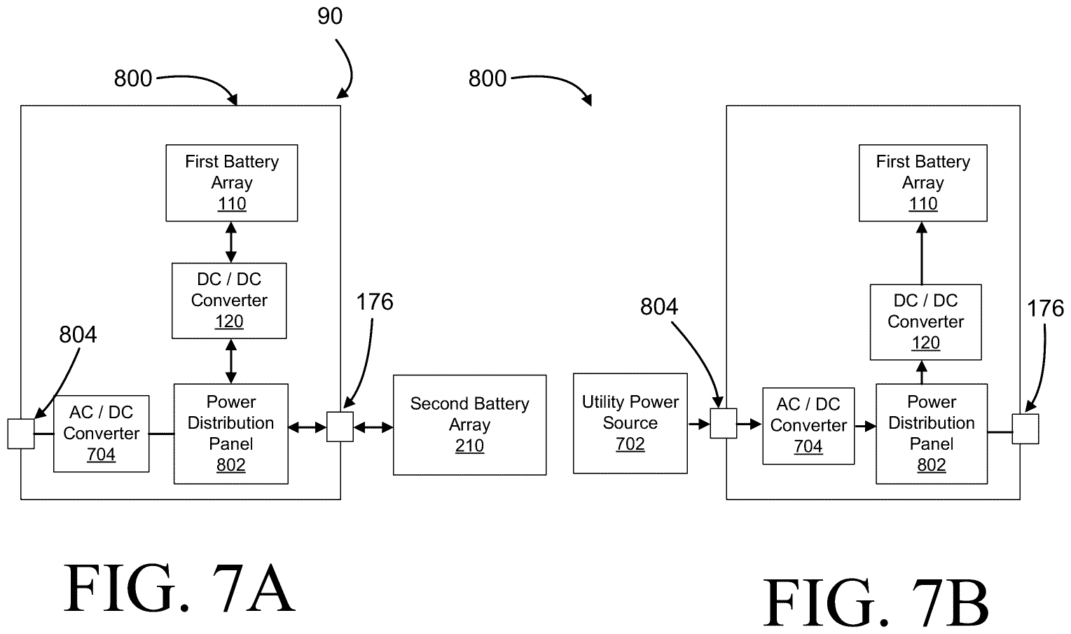

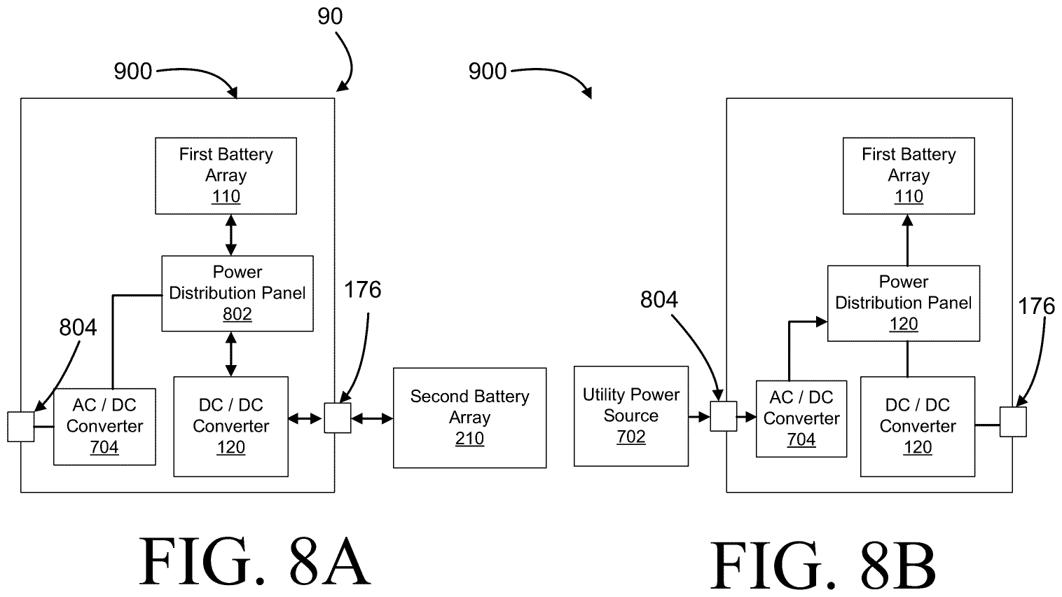

Although illustrated as having the AC/DC converter 704 being external to the mobile charging system 100, the present disclosure is not limited in this regard. For example, with reference now to FIGS. 7A, 7B, 8A, and 8B, schematic views of an electric vehicle charging ecosystem 90 with a mobile charging system 800, 900 (FIGS. 7A, 8A) and schematic systems of the mobile charging system 800, 900 during charging (FIG. 7B, 8B) are illustrated, in accordance with various embodiments. The mobile charging systems 800, 900 may be in accordance with the mobile charging system 100 from FIGS. 2A, 2B, and 6A-B except as otherwise described herein. The mobile charging system 800 may further comprise the AC/DC converter 704, a power distribution panel 802 and a second charging interface 804. In various embodiments, the power distribution panel 802 may be coupled to the DC converter 120 and be in electrical communication with both the charging interface 176 and the second charging interface 804. In this regard, the power distribution panel 802 is configured to distribute power based on a configuration of the mobile charging system 800.

In various embodiments, the mobile charging system 900 of FIGS. 8A-B may comprise a single electrical interface (e.g., charging interface 176) by orienting the AC/DC converter 704 in parallel with the DC converter 120 between the power distribution panel 802 and the first battery array 110. In various embodiments, mobile charging system 900 may be a simpler configuration relative to mobile charging systems 100, 800 where only one set of power conversions is utilized as long as the AC/DC converter 704 can be controlled (e.g., via power distribution panel 802) to provide variable voltage, power, and current.

For example, with reference now to FIG. 7A in an electric vehicle charging configuration, and in the charging mode (e.g., charging step 16 of method 10 from FIG. 1) described previously herein, the power distribution panel 802 is configured to shuttle voltage, through the bi-directional DC/DC converter 120 from the first battery array 110 to the second battery array 210.

Referring now to FIG. 7B, when the mobile charging system 800 is configured to charge the first battery array 110, the utility power source 702 is electrically coupled to the second charging interface 804. Disposed between the second charging interface 804 and the power distribution panel 802 is the AC/DC converter 704. Thus, the first battery array 110 may be charged by coupling the second charging interface 804 to the utility power source 702 and shuttling an alternating current through the AC/DC converter 704 to the power distribution panel 802, through the bi-directional DC/DC converter 120 to the first battery array 110 of the mobile charging system 800. In various embodiments, the mobile charging system 800 may be advantageous relative to the mobile charging system 100 by having the AC/DC converter 704 as a component of the mobile charging system 800. In contrast, the mobile charging systems 100, 900 may be advantageous relative to the mobile charging system 800 by having a singular charging interface (e.g., charging interface 176) regardless of configuration, and having fewer components. However, mobile charging systems 100, 800, 900 are advantageous over typical charging systems for reasons disclosed previously herein.

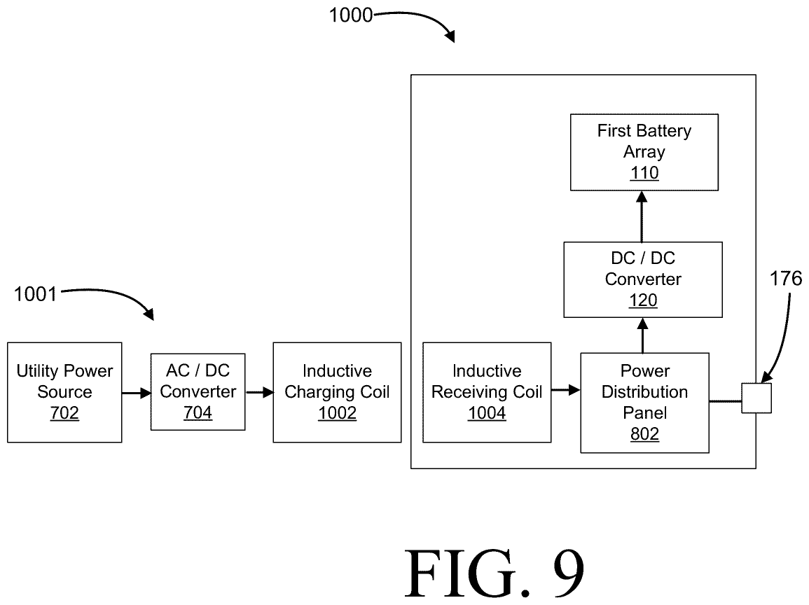

Although illustrated as being configured for wired charging of the first battery array 110, the present disclosure is not limited in this regard. For example, with reference now to FIG. 9, schematic view of a charging system 1001 of the mobile charging system 1000 configured for wireless charging of the first battery array 110 is illustrated in accordance with various embodiments. In various embodiments, the charging system 1001 may comprise an inductive charging coil 1002 in electrical communication with the AC/DC converter 704 and the utility power source 702, all of which are external to the mobile charging system 1000. The mobile charging system 1000 may be in accordance with the mobile charging system 100 except as otherwise described herein. The mobile charging system 1000 may comprise an inductive receiving coil 1004 configured to wirelessly communicate with the inductive charging coil 1002 during charging of the first battery array 110. In this regard, the charging system 1001 may be configured to wirelessly charge the first battery array 110 through the inductive charging coil 1002 and the inductive receiving coil 1004 as illustrated in FIG. 9, in accordance with various embodiments.

While the principles of this disclosure have been shown in various embodiments, many modifications of structure, arrangements, proportions, elements, materials and components (which are particularly adapted for a specific environment and operating requirements) may be used without departing from the principles and scope of this disclosure. These and other changes or modifications are intended to be included within the scope of the present disclosure and may be expressed in the following claims.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure Likewise, benefits, other advantages, and solutions to problems have been described above with regard to various embodiments.

However, benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

When language similar to “at least one of A, B, or C” or “at least one of A, B, and C” is used in the claims or specification, the phrase is intended to mean any of the following: (1) at least one of A; (2) at least one of B; (3) at least one of C; (4) at least one of A and at least one of B; (5) at least one of B and at least one of C; (6) at least one of A and at least one of C; or (7) at least one of A, at least one of B, and at least one of C.

We claim:

1. A mobile charging system, comprising:
a vehicle comprising an electrical system and a motive power system; and
a first battery array coupled to the vehicle, the first battery array electrically isolated from the electrical system and the motive power system of the vehicle, the mobile charging system configured to electrically couple the first battery array to a second battery array of an electric vehicle, the mobile charging system configured to charge the second battery array via the first battery array.

2. The mobile charging system of claim 1, wherein the electric vehicle comprises an electrically powered aircraft.

3. The mobile charging system of claim 1, further comprising a thermal management system coupled to the vehicle, wherein the mobile charging system is configured to thermally manage the second battery array via the thermal management system during charging.

4. The mobile charging system of claim 1, further comprising
a charger in electrical communication with the first battery array, the charger including an electrical connector configured to electrically couple the first battery array to the second battery array of a battery system of the electric vehicle;
a thermal management system;
a supply line extending from the thermal management system to a first fitting; and
a return line extending from the thermal management system to a second fitting, the first fitting configured to fluidly couple the supply line to the battery system of the electric vehicle, the second fitting configured to fluidly couple the return line to the battery system.

5. The mobile charging system of claim 4, wherein:
the vehicle is configured to transport the first battery array from a first location to a second location,
the first location is a fixed electrical grid and the second location is proximal the electric vehicle, and
the electric vehicle is an electrically powered aircraft.

6. The mobile charging system of claim 4, further comprising a purge and fill system, a first three-way valve and a second three-way valve, the purge and fill system in fluid communication with the first three-way valve and the second three-way valve, wherein the first three-way valve includes a first inlet in fluid communication with the thermal management system and a second inlet in fluid communication with the purge and fill system.

7. The mobile charging system of claim 4, further comprising electrical cables and a cable refrigeration module, the electrical cables extending from the first battery array to the charger, the mobile charging system configured to cool the electrical cables during charging of the electric vehicle via the cable refrigeration module.

8. An electric vehicle charging ecosystem, comprising:
a mobile charging system, comprising:
a thermal management system, and
a first battery array in electrical communication with a charger, the mobile charging system configured to transport the first battery array from a first location to a second location, and
a second battery array configured for powering an electric vehicle, the mobile charging system configured to electrically couple the first battery array to the second battery array by the charger and configured to fluidly couple the thermal management system to a battery system including the second battery array.

9. The electric vehicle charging ecosystem of claim 8, wherein the electric vehicle is an electric aircraft.

10. The electric vehicle charging ecosystem of claim 8, wherein the first battery array is configured to be charged via a fixed electrical grid.

11. The electric vehicle charging ecosystem of claim 10, wherein the first location is the fixed electrical grid and the second location is proximal to the electric vehicle.

12. The electric vehicle charging ecosystem of claim 8, further comprising a battery management system and automatic payment system, the battery management system configured to determine a power usage during a charging cycle.

13. The electric vehicle charging ecosystem of claim 12, wherein the battery management system is configured to receive an identifier associated with the electric vehicle and transmit the identifier to the automatic payment system.

14. The electric vehicle charging ecosystem of claim 13, wherein the automatic payment system is configured to automatically charge a payment method associated with the identifier based on the power usage during the charging cycle.

15. A method of using a mobile charging system, the method comprising:
transporting a charging system from a first location to a second location;
electrically coupling, through a connector of the mobile charging system, a first battery array of the mobile charging system to a second battery array of an electrically powered aircraft;
coupling a plumbing system of the mobile charging system to the electrically powered aircraft;
charging the second battery array of the electrically powered aircraft via the first battery array of the mobile charging system, charging the second battery array including heating the first battery array via a fluid being cycled through the plumbing system; and
purging the fluid from the electrically powered aircraft.

16. The method of claim 15, further comprising powering the electrically powered aircraft with the second battery array.

17. The method of claim 15, further comprising heating, via a second thermal management system of the mobile charging system, the second battery array of the electrically powered aircraft.

18. The method of claim 17, wherein the heating of the second battery array is performed prior to the charging the second battery array.

19. The method of claim 15, further comprising transporting the charging system from the second location to a third location, and charging a third battery array of a second electrically powered aircraft via the first battery array of the mobile charging system.

20. The method of claim 15, further comprising cooling electrical cables of mobile charging system during the charging of the second battery array.
